(19) United States
(12) Patent Application Publication
(10) Pub. No.: US 2026/0161092 A1
(43) Pub. Date: Jun. 11, 2026

(54) POSITIVE TONE METAL OXIDE RESIST DEVELOPMENT

(71) Applicant: Applied Materials, Inc., Santa Clara, CA (US)

(72) Inventors: Nasrin Kazem, Santa Clara, CA (US); Rudy Wojtecki, East Garrison, CA (US)

(21) Appl. No.: 19/402,466

(22) Filed: Nov. 26, 2025

Related U.S. Application Data
(60) Provisional application No. 63/728,635, filed on Dec. 5, 2024.

(51) Int. Cl. G03F 7/32; G03F 7/004; G03F 7/36; G03F 7/38

(52) U.S. Cl. CPC G03F 7/325; G03F 7/0043; G03F 7/36; G03F 7/38

(57) ABSTRACT

Embodiments described herein relate to a method of treating a resist layer that includes a metal-oxide material that has been selectively exposed with radiation to form an exposed region and an unexposed region. In an embodiment, the method includes treating the resist layer with a treatment that attaches a self-assembled monolayer (SAM) to metal cages of the metal-oxide material in the exposed region, and exposing the resist layer to radiation to modify a chemical structure of the metal-oxide material in the unexposed region. In an embodiment, the method further includes heating the resist layer to drive a condensation reaction in the unexposed region.

### CROSS-REFERENCE TO RELATED APPLICATIONS

This application claims the benefit of U.S. Provisional Application No. 63/728,635, filed on Dec. 5, 2024, the entire contents of which are hereby incorporated by reference herein.

### BACKGROUND

### 1) Field

Embodiments relate to the field of semiconductor manufacturing and, in particular, positive tone metal-oxide resist materials.

### 2) Description of Related Art

Extreme ultraviolet (EUV) photoresists allow for the continued scaling to smaller features that are patterned on a semiconductor substrate. In an EUV lithography process, EUV radiation is selectively applied to regions of the photoresist layer in order to generate a solubility switch that enables the formation of a latent image within the photoresist layer. The latent image corresponds to the portions of the photoresist layer that have undergone the solubility switch as a result of a chemical reaction that is induced by the EUV exposure. After the latent image is produced within the photoresist layer, a developing process may be used in order to generate a pattern in the photoresist layer.

Holes are patterned into the resist layers in order to form contacts or vias that are used to electrically couple traces in different layers together. Typically, positive tone resists are used for such patterning. Chemically amplified resist (CAR) materials are the dominant positive tone EUV resist currently used in industry. However, CAR materials are approaching their limits as technology advances to smaller pitches.

### SUMMARY

Embodiments described herein relate to a method of treating a resist layer that includes a metal-oxide material that has been selectively exposed with radiation to form an exposed region and an unexposed region. In an embodiment, the method includes treating the resist layer with a treatment that attaches a self-assembled monolayer (SAM) to metal cages of the metal-oxide material in the exposed region, and exposing the resist layer to radiation to modify a chemical structure of the metal-oxide material in the unexposed region. In an embodiment, the method further includes heating the resist layer to drive a condensation reaction in the unexposed region.

Embodiments described herein relate to a method of treating a resist layer that includes a metal-oxide material that has been selectively exposed with radiation to form an exposed region and an unexposed region. In an embodiment, the method includes treating the resist layer with a treatment that attaches a self-assembled monolayer (SAM) to metal cages of the metal-oxide material in the exposed region, and forming a protective layer over the unexposed region with a selective deposition process.

Embodiments described herein relate to a method of treating a resist layer that includes a metal-oxide material that has been selectively exposed with radiation to form an exposed region and an unexposed region. In an embodiment, the method includes treating the resist layer with a treatment that attaches a self-assembled monolayer (SAM) to metal cages of the metal-oxide material in the exposed region, and exposing the resist layer to radiation to modify a chemical structure of the metal-oxide material in the unexposed region. In an embodiment, the method further includes forming a protective layer over the unexposed region with a selective deposition process.

### BRIEF DESCRIPTION OF THE DRAWINGS

FIGS. 1A-1D are cross-sectional illustrations depicting a process of converting a metal oxide resist (MOR) from a negative tone resist to a positive tone resist, in accordance with an embodiment.

FIGS. 2A-2F are cross-sectional illustrations depicting a process for developing a MOR as a positive tone resist, in accordance with an embodiment.

FIG. 3 is a flow diagram of a process for developing a MOR as a positive tone resist, in accordance with an embodiment.

FIG. 4 is a cross-sectional illustration of a MOR that has a selectively formed protection layer to allow for better selectivity, in accordance with an embodiment.

FIG. 5A-5C are cross-sectional illustrations depicting a process for developing a MOR as a positive tone resist using a selectively formed protection layer, in accordance with an embodiment.

FIG. 6 is a flow diagram of a process for developing a MOR as a positive tone resist with a protection layer, in accordance with an embodiment.

FIG. 7 is a cross-sectional illustration of a MOR that has a selectively formed protection layer to allow for better selectivity, in accordance with an embodiment.

FIGS. 8A-8C are cross-sectional illustrations depicting a process for developing a MOR as a positive tone resist using a selectively formed protection layer, in accordance with an embodiment.

FIG. 9 is a flow diagram of a process for developing a MOR as a positive tone resist with a protection layer, in accordance with an embodiment.

FIG. 10 illustrates a block diagram of an exemplary computer system that may be used in conjunction with a processing tool, in accordance with an embodiment.

### DETAILED DESCRIPTION

Embodiments described herein include positive tone metal-oxide resist (MOR) materials. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, chemically amplified resist (CAR) materials are typically used when positive tone resists are desired. For example, when a contact hole or via hole is needed, a CAR material is used as the resist to form the hole. However, as dimensions continue to scale to smaller critical dimensions (CDs), the patterning limits of CAR materials are being approached. Metal-oxide resist (MOR) materials provide better patterning performance at small dimensions (compared to CAR materials). However, MOR materials are generally only available as a negative tone resist.

Accordingly, embodiments disclosed herein include different treatment processes that may convert a negative tone MOR into a positive tone MOR. The conversion process may be implemented after an exposure process. The selective exposure of the MOR allows for a chemical difference between the exposed region and the unexposed region. This chemical difference can be leveraged in order to selectively modify the exposed region so that the exposed region becomes soluble in a solution that will not dissolve the unexposed region. Selective removal of the exposed region results in the formation of a positive tone resist.

The use of positive tone MOR materials provides several advantages over existing positive tone CAR materials. For example, positive tone MOR materials allow for higher resolution and pattern fidelity compared to positive tone CAR materials. Positive tone MOR materials also provide superior sensitivity and enable lower extreme ultraviolet (EUV) doses. EUV sensitivity is a significant issue in EUV lithography. Improvements in sensitivity allow for better throughput. Additionally, positive tone MOR materials may provide better etch resistance than positive tone CAR materials. This allows for thinner resist layers, which can further reduce EUV dosages and/or improve patterning metrics.

In one embodiment, the process to convert a negative tone MOR to a positive tone MOR may include exposing the exposed MOR material to a self-assembled monolayer (SAM) chemistry. The SAM chemistry selectively reacts with the OH groups of metal cages of the MOR material. The metal cages are passivated by the SAM layer. A subsequent exposure to radiation (e.g., ultraviolet (UV) radiation) allows the unexposed region to form OH groups. A subsequent heating process leads to a condensation reaction in the unexposed region that provides etch selectivity to the unexposed region. A non-polar solvent can then be used to dissolve the SAM coated metal cages in the exposed region.

In another embodiment, a protection layer is selectively formed over the unexposed region of the MOR material. The protection layer may be formed with an area selective deposition (ASD) process that leverages a chemical contrast between SAM coated metal cages of the exposed region and the metal cages of the unexposed regions. In some embodiments, the metal cages in the unexposed region may have alkyl group terminations. In other embodiments, the alkyl groups may be modified with a UV exposure to form metal cages with OH terminations in order to further enhance the chemical contrast between the exposed region and the unexposed region.

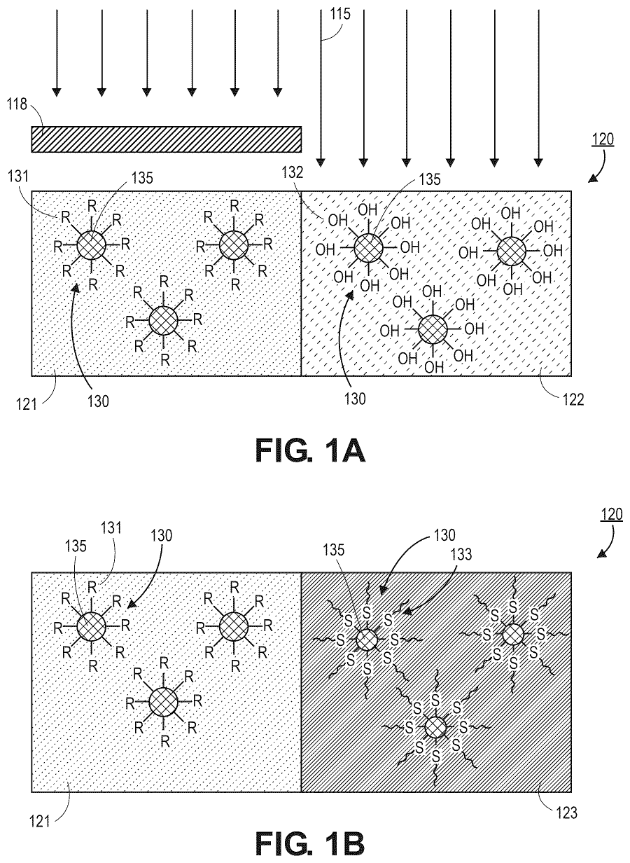

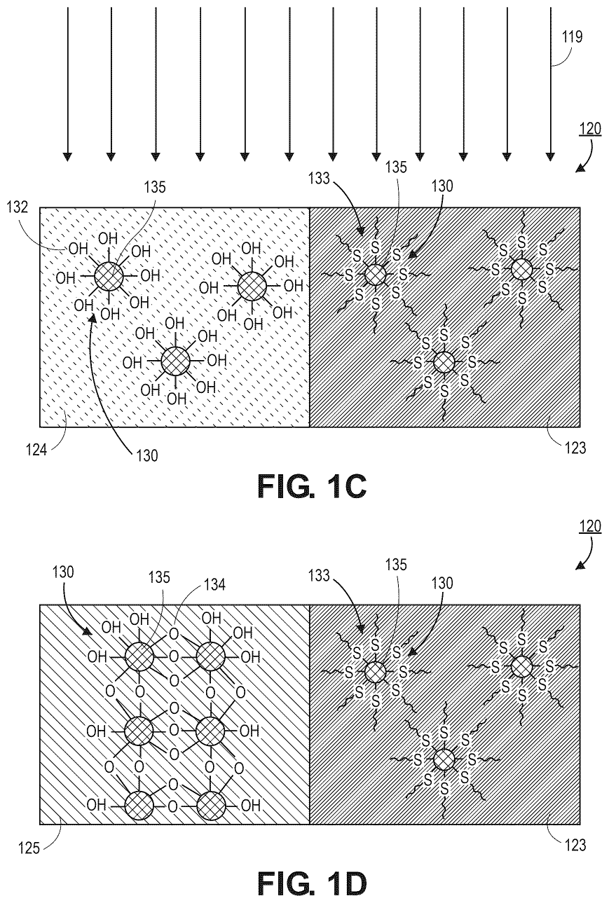

Referring now to FIGS. 1A-1D , a series of cross-sectional illustrations depicting a process for converting a MOR material from a negative tone resist to a positive tone resist is shown, in accordance with an embodiment. In the illustrated embodiment, the resist layer 120 is a MOR material that is shown in isolation of any underlying layers for simplicity. Though, as will be described in greater detail herein, the resist layer 120 may be provided over an underlayer, a patterning stack, and/or a substrate.

Referring now to FIG. 1A, a cross-sectional illustration of a resist layer 120 is shown, in accordance with an embodiment. In an embodiment, the resist layer 120 may comprise a MOR material. For example, the resist layer 120 may comprise metal cages 130. The metal cages 130 may comprise a metal-oxide cluster 135. The metal-oxide cluster 135 may comprise one or more metal atoms and one or more oxygen atoms that are bonded together. In some embodiments, the metal within the metal-oxide clusters 135 may comprise one or more of tin, indium, hafnium, zinc, zirconium, or any combination thereof. The MOR material of the metal cages 130 may also comprise an organotin-oxide material, an organoindium-oxide material, or the like.

In an embodiment, the resist layer 120 may comprise an exposed region 122 and an unexposed region 121. A mask 118 or the like may be used to block radiation 115 (e.g., EUV radiation or deep ultraviolet (DUV) radiation). In an embodiment, the radiation 115 may result in a chemical reaction in the metal cages 130 within the exposed region 122. For example, the metal cages 130 in the unexposed region 121 may have alkyl terminations 131, and the metal cages 130 in the exposed region 122 may have hydroxyl (OH) terminations 132 after the radiation 115.

Referring now to FIG. 1B, a cross-sectional illustration of the resist layer 120 after a treatment is shown, in accordance with an embodiment. In an embodiment, the treatment may include applying a SAM chemistry to the resist layer 120. The SAM chemistry may be a liquid or a gas. In some embodiments, the SAM chemistry may comprise alkanethiols, alkylsilanes, or any other suitable SAM chemistry. In an embodiment, the SAM chemistry may preferentially react with the hydroxyl terminations 132 of the metal cages 130 in the exposed region 122 to form a SAM layer 133. For example, a SAM layer 133 with sulfur and alkyl chains may be coupled to the metal cages 130. The SAM layer 133 may passivate the metal cages 130.

Referring now to FIG. 1C, a cross-sectional illustration of the resist layer 120 after a blanket exposure of radiation 119 (e.g., UV radiation, DUV radiation, EUV radiation, etc.) is shown, in accordance with an embodiment. In an embodiment, the blanket exposure may include an exposure of both the unexposed region 121 and the exposed region 123. The passivation provided by the SAM layer 133 prevents further modification of the exposed region 123. The unexposed region 121 may undergo a chemical change as a result of the exposure to the radiation 119 in order to form unexposed region 124. For example, the alkyl terminations 131 may be converted to hydroxyl (OH) terminations 132. In an embodiment, the alkyl terminations 131 are preferentially converted over the SAM layer 133 as a result of different carbon chain lengths. For example, the alkyl terminations 131 are shorter than the carbon chains of the SAM layer 133. In some embodiments, the alkyl terminations 131 may be up to five carbons long, and the SAM layer 133 may have carbon chains that are four carbons or more.

Referring now to FIG. 1D, a cross-sectional illustration of the resist layer 120 after heating the resist layer 120 is shown, in accordance with an embodiment. In an embodiment, heating the resist layer 120 may result in a condensation reaction that drives oxygen bonding 134 between metal-oxide clusters 135 of the metal cages 130 in unexposed region 124 to form modified unexposed region 125. The cross-linking of the metal cages 130 improves the etch resistance in subsequent developing process. The resist layer 120 in FIG. 1D may be developed with a non-polar solvent that is capable of dissolving the metal cages 130 with the SAM layer 133 of the exposed region 122. That is, the exposed region 122 is the region of the resist layer 120 that is removed during development. As such, the MOR resist layer 120 has been converted into a positive tone resist layer 120.

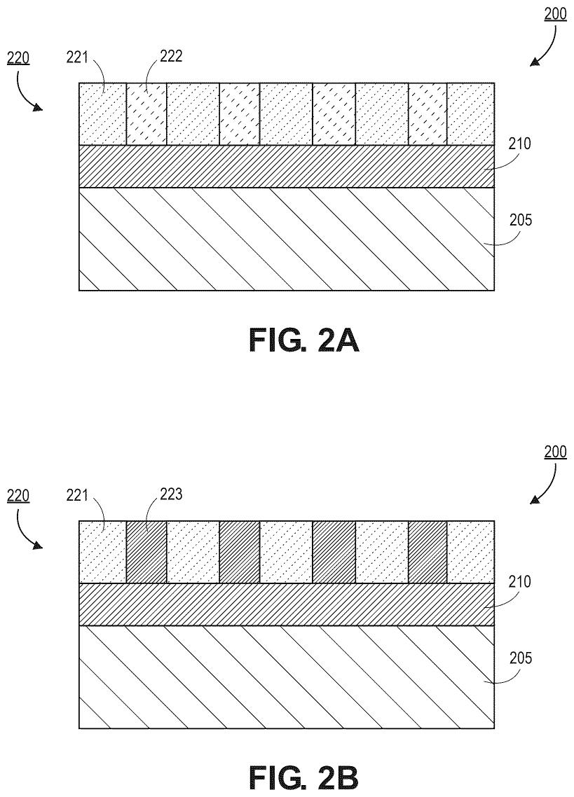

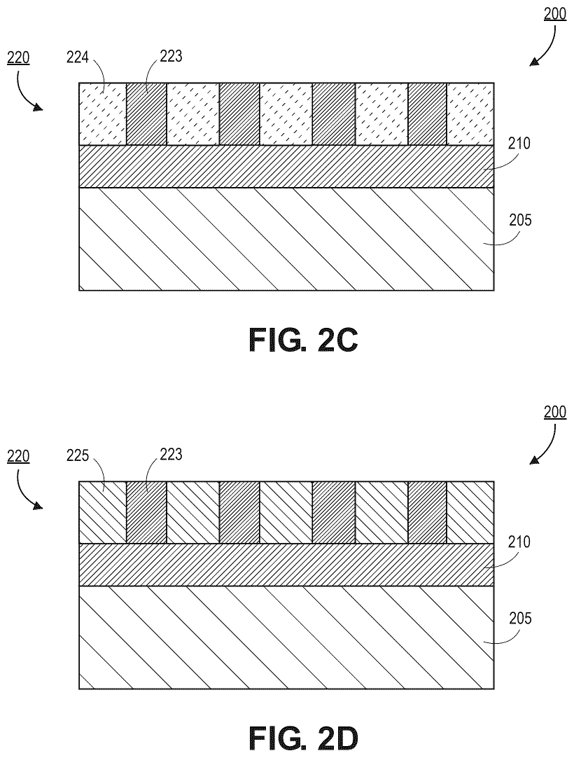

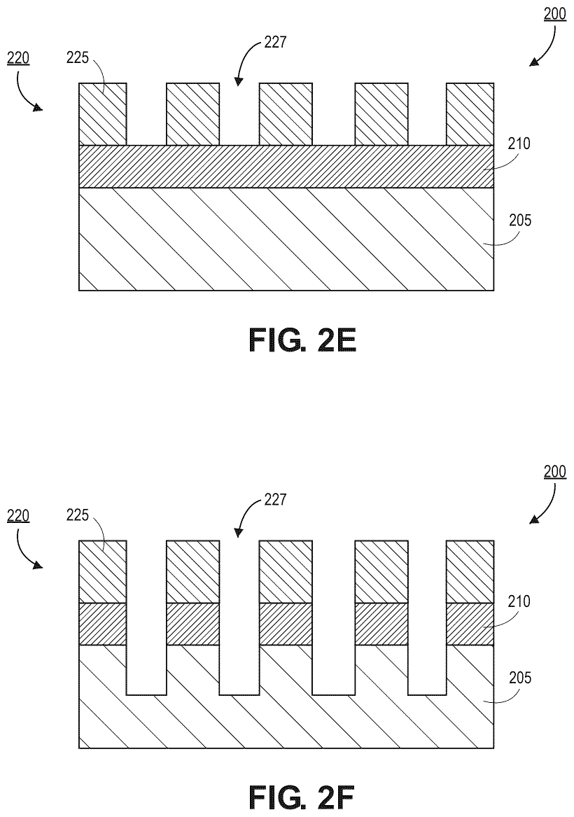

Referring now to FIGS. 2A-2F , a series of cross-sectional illustrations depicting a process for developing a resist layer 220 is shown, in accordance with an embodiment. In an embodiment, the resist layer 220 is a MOR material that is converted from a negative tone resist to a positive tone resist after an initial exposure is shown, in accordance with an embodiment.

Referring now to FIG. 2A, a cross-sectional illustration of a device 200 is shown, in accordance with an embodiment. In an embodiment, the device 200 may comprise a substrate 205. In an embodiment, the substrate 205 may comprise a semiconductor material, such as a silicon wafer, an oxide layer, a nitride layer, a metallic layer, or the like. In an embodiment, a patterning stack (not shown) may be provided over the substrate 205. For example, the patterning stack may include one or more layers suitable for transferring a pattern formed into the resist layer 220 into the underlying substrate 205. For example, the patterning stack may comprise multiple layers, such as a silicon hardmask layer, a carbon hardmask layer, an antireflective coating, and/or the like. In some embodiments, reference to the substrate 205 herein may also refer to the patterning stack between the substrate 205 and an underlayer 210.

In some embodiments, the material for the underlayer 210 may be a material that is compatible with patterning stack deposition processes and are structurally similar to existing polymer underlayer materials. In an embodiment, the underlayer 210 may comprise a material that is sensitive to EUV or DUV radiation in order to generate species (e.g., elements, molecules, electrons, etc.) that can diffuse into the overlying resist layer 220 in order to participate in the solubility switch reaction. In an embodiment, the underlayer 210 may be deposited with a dry deposition process (e.g., chemical vapor deposition (CVD), atomic layer deposition (ALD), or the like).

In an embodiment, the resist layer 220 may comprise a material that reacts when exposed to EUV and/or DUV radiation in order to generate a solubility switch. In a particular embodiment, the resist layer 220 may comprise a MOR material. In an embodiment a MOR material may comprise a photoresist material with one or more metals (e.g., tin, indium, hafnium, zinc, zirconium, or any combination thereof). The MOR material may also comprise an organotin-oxide photoresist material, an organoindium-oxide photoresist material, or the like. In an embodiment, the resist layer 220 may be similar to the resist layer 120 described in greater detail above.

The resist layer 220 may have been exposed with radiation to form exposed regions 222 and unexposed regions 221. In an embodiment, the resist layer 220 may be selectively exposed with EUV and/or DUV radiation. For example, the radiation may be passed through a reticle, a mask, direct laser writing, or the like. In an embodiment, the exposed regions 222 may be columns so that via openings may be formed in the underlying substrate 205. In an embodiment, the exposed regions 222 may have metal cages (not individually shown) that have alkyl terminations replaced with hydroxyl (OH) terminations. For example, the exposed regions 223 in FIG. 2A may be similar to the exposed region 123 in FIG. 1A.

Referring now to FIG. 2B, a cross-sectional illustration of the device 200 after a treatment is applied to the resist layer 220 is shown, in accordance with an embodiment. In an embodiment, the treatment may include exposing the resist layer to a SAM chemistry. The SAM chemistry may comprise a liquid exposure or a gas exposure. For example, the SAM chemistry may include exposure to alkanethiols, alkylsilanes, or the like. Such a process may result in the formation of an exposed region 223 that includes metal cages with a passivating SAM layer. For example, the metal cages may be similar to the metal cages 130 in the exposed region 123 in FIGS. 1B-1C . For example, the SAM layer may comprise a sulfur bonded to the metal cage with alkyl chains extending out from the sulfur. As such, the metal cages may be substantially passivated by the SAM layer.

Referring now to FIG. 2C, a cross-sectional illustration of the device 200 after the resist layer 220 is exposed to a blanket radiation exposure is shown, in accordance with an embodiment. In an embodiment, the radiation may be UV radiation, DUV radiation, or EUV radiation. The blanket exposure results in the unexposed regions 221 being modified chemically to form treated unexposed regions 224. In some embodiments, the treated unexposed regions 224 may have metal cages with hydroxyl terminations, similar to the unexposed regions 124 shown in FIG. 1C.

Referring now to FIG. 2D, a cross-sectional illustration of the device 200 after the resist layer 220 is heated is shown, in accordance with an embodiment. In an embodiment, the heating treatment may result in a condensation reaction within the treated unexposed regions 224 to form a cross-linked region 225. The cross-linked region 225 may include oxygen bonds between metal cages, similar to the embodiment shown in FIG. 1D. However, due to the SAM layer in the exposed region 223, the exposed region 223 may not undergo any substantial chemical changes.

Referring now to FIG. 2E, a cross-sectional illustration of the device 200 after a developing process is shown, in accordance with an embodiment. In an embodiment, the developing process may include exposing the resist layer 220 to a developing chemistry that selectively removes the exposed regions 223. For example, a non-polar solvent may be used to selectively dissolve the SAM-passivated metal cages of the exposed regions 223. Removal of the exposed regions 223 may result in the formation of openings 227 through a thickness of the resist layer 220.

Referring now to FIG. 2F, a cross-sectional illustration of the device 200 after a pattern of the openings 227 is transferred into the underlying layers is shown, in accordance with an embodiment. In an embodiment, the underlayer 210 and the substrate 205 may be etched with one or more etching processes, such as a wet etching process, a dry etching process or the like. The cross-linked region 225 of the resist layer 220 may remain as a mask layer for one or more etching processes used to transfer the pattern of the openings 227 into the underlying layers. Further, due to the cross-linked nature of the cross-linked regions 225, the etch resistance of the resist layer 220 is improved over existing solutions. As such, the resist layer 220 may be made thinner. This can provide improved patterning metrics, as well as reducing the dose necessary to generate the solubility switch in the resist layer 220. Accordingly, throughput may be improved without negatively impacting the lithography process.

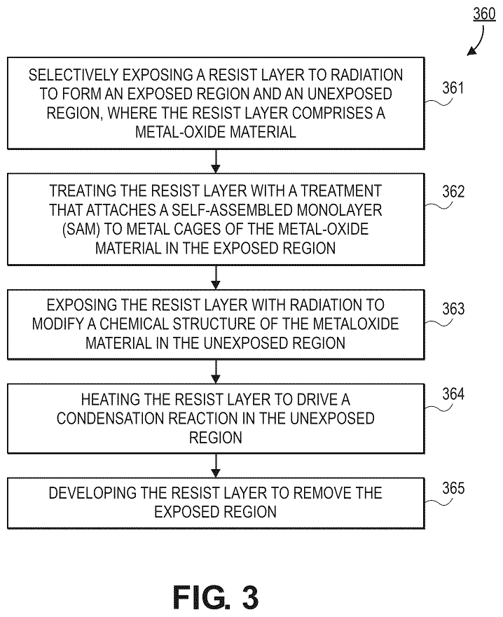

Referring now to FIG. 3, a flow diagram of a process 360 for developing a resist layer is shown, in accordance with an embodiment. In an embodiment, the resist layer may be a MOR material that is converted from a negative tone resist to a positive tone resist after radiation exposure. For example, the process 360 may be similar to the process described above with respect to FIGS. 2A-2F .

In an embodiment, the process 360 may begin with operation 361, which comprises selectively exposing a resist layer to radiation to form an exposed region and an unexposed region. In an embodiment, the radiation may include EUV radiation or DUV radiation. The resist layer may include a metal-oxide material, such as any of the MOR materials described in greater detail herein.

In an embodiment, the process 360 may continue with operation 362, which comprises treating the resist layer with a treatment that attaches a SAM to metal cages of the metal-oxide material in the exposed region. For example, the metal cages in the exposed region may have hydroxyl groups that react with sulfur of the SAM. In an embodiment, the treatment to attach the SAM to the metal cages is performed after the radiation exposure and before any significant heating of the resist layer. As such, hydroxyl groups of the exposed region are not able to react (e.g., in a decomposition reaction) before the SAM is attached.

In an embodiment, the process 360 may continue with operation 363, which comprises exposing the resist layer with radiation to modify a chemical structure of the metal-oxide material in the unexposed region. The radiation exposure may include UV radiation, DUV radiation, or EUV radiation. The exposure may be a blanket exposure (i.e., without a mask). The metal cages in the exposed region are protected from further chemical change by the SAM, and the metal cages in the unexposed region may be altered to have hydroxyl terminations.

In an embodiment, the process 360 may continue with operation 364, which comprises heating the layer to drive a condensation reaction in the unexposed region. The condensation reaction may include a cross-linking that is driven by oxygen bonding between the metal cages. The metal cages in the exposed region are prevented from further chemical change due to the presence of the SAM.

In an embodiment, the process 360 may continue with operation 365, which comprises developing the resist layer to remove the exposed region. In an embodiment, the exposed region may be dissolved by exposing the resist layer to a non-polar solvent. The modified unexposed region remains substantially unaltered by the developing process in order to provide a developed positive tone resist.

In an embodiment, the developed resist may then be used as a mask layer in order to pattern underlying layers (e.g., similar to the embodiment described above with respect to FIGS. 2A-2F .

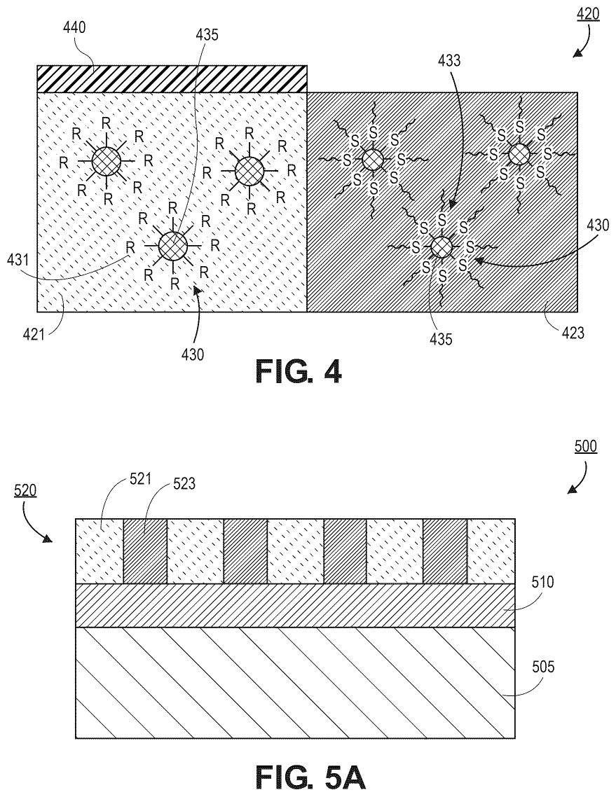

In some embodiments, a developed positive tone MOR may also be modified to have improved etch resistance by the formation of a protection layer over the unexposed region of the resist layer. The protection layer may be selectively deposited over the unexposed region by leveraging chemical differences between the metal cages of the exposed region (which may be surrounded by SAMs) and the metal cages of the unexposed region. An example of such an embodiment is shown in FIG. 4.

Referring now to FIG. 4, a cross-sectional illustration of a resist layer 420 is shown, in accordance with an embodiment. In an embodiment, the resist layer 420 may be similar to the resist layer 120 shown in FIG. 1B. That is, an exposed region 423 may include metal cages 430 with metal-oxide clusters 435 that are surrounded by a SAM 433, and the unexposed region 421 may include metal cages 430 with metal-oxide clusters 435 that have alkyl terminations 431. In an embodiment, the reactivity differences between the alkyl terminations 431 and the SAMs 433 may be used to selectively deposit a protection layer 440 over the unexposed region 421.

In an embodiment, the protection layer 440 may be formed with an ASD process or the like. For example, a chemical vapor deposition (CVD) process, an atomic layer deposition (ALD) process, or the like may be used to deposit the protection layer 440. In an embodiment, the protection layer 440 may be a low-k dielectric material. For example, the protection layer 440 may comprise SiOC, HfOₓ, or SnOₓ. The presence of the protection layer 440 may be used to improve the selectivity of the resist layer 420 developing process and/or improve etch resistance of the resist layer 420 during pattern transfer into underlying layers.

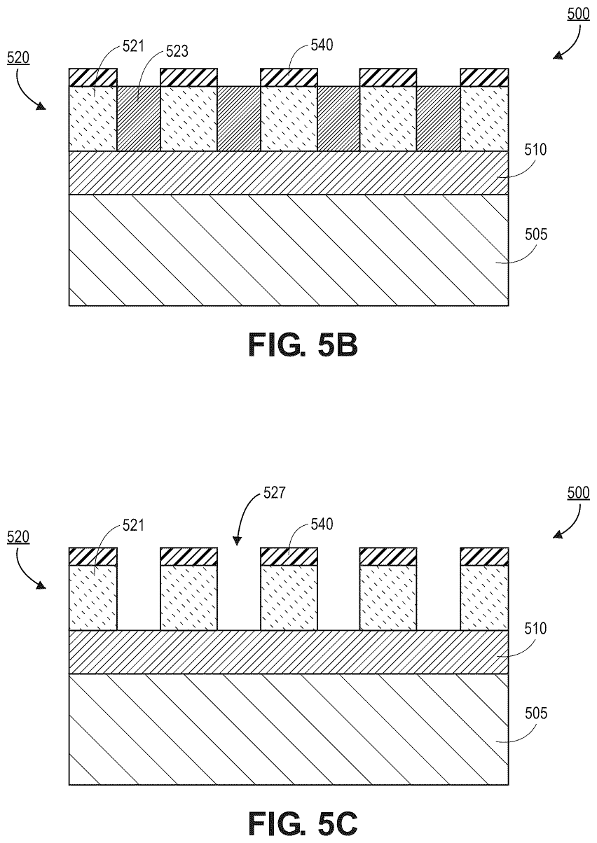

Referring now to FIGS. 5A-5C , a series of cross-sectional illustrations of a device 500 that includes a resist layer 520 that is converted from a negative tone resist into a positive tone resist is shown, in accordance with an embodiment.

Referring now to FIG. 5A, a cross-sectional illustration of the device 500 with a resist layer 520 over an underlayer 510 and a substrate 505 is shown, in accordance with an embodiment. In an embodiment, the device 500 in FIG. 5A may be similar to the device 200 in FIG. 2B. That is, the resist layer 520 may comprise a MOR material that has been exposed to include exposed regions 523 and unexposed regions 521. The exposed regions 523 may be treated so that a SAM is provided around the metal cages of the MOR material. The process to form the device 500 in FIG. 5A may be similar to the processing used to form the device 200 in FIG. 2B.

Referring now to FIG. 5B, a cross-sectional illustration of the device 500 after a protection layer 540 is selectively formed over the unexposed regions 521 of the resist layer 520 is shown, in accordance with an embodiment. In an embodiment, the unexposed regions 521 of the resist layer 520 may have a chemical contrast to the SAMs in the exposed regions 523. As such, an ASD process, such as one similar to the any of the ASD processes described herein, may be used in order to selectively form the protection layer 540 over the unexposed regions 521. That is, the exposed regions 523 remain exposed in FIG. 5B. In an embodiment, the protection layer 540 may be a low-k dielectric material. For example, the protection layer 540 may comprise SiOC, HfOₓ, or SnOₓ.

Referring now to FIG. 5C, a cross-sectional illustration of the device 500 after the resist layer 520 is developed is shown, in accordance with an embodiment. In an embodiment, the resist layer 520 may be developed with a non-polar solvent or the like. The non-polar solvent may selectively dissolve the SAM coated metal cages of the exposed regions 523 in order to form openings 527 through the resist layer 520. For example, the openings 527 may be holes that are used in the formation of vias in the underlying substrate 505. After the openings 527 are formed with the developing process, a pattern of the openings 527 may be transferred into the underlayer 510 and the substrate 505 using processes similar to any of those described with respect to FIG. 2F above.

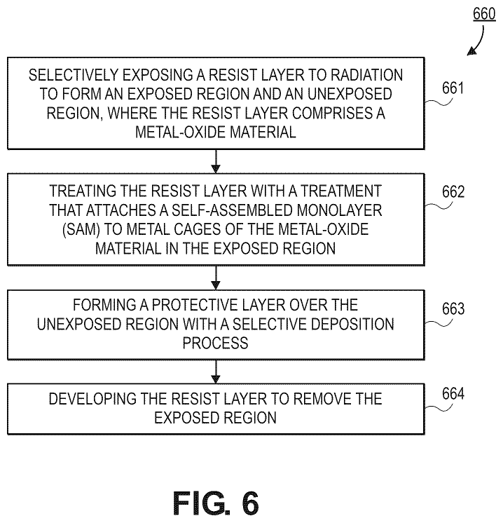

Referring now to FIG. 6, a flow diagram of a process 660 for developing a resist layer is shown, in accordance with an embodiment. In an embodiment, the resist layer may be a MOR material that is converted from a negative tone resist to a positive tone resist after radiation exposure. For example, the process 660 may be similar to the process described above with respect to FIGS. 5A-5C .

In an embodiment, the process 660 may begin with operation 661, which comprises selectively exposing a resist layer to radiation to form an exposed region and an unexposed region. In an embodiment, the radiation may include EUV radiation or DUV radiation. The resist layer may include a metal-oxide material, such as any of the MOR materials described in greater detail herein.

In an embodiment, the process 660 may continue with operation 662, which comprises treating the resist layer with a treatment that attaches a SAM to metal cages of the metal-oxide material in the exposed region. For example, the metal cages in the exposed region may have hydroxyl groups that bond with sulfur of the SAM. In an embodiment, the treatment to attach the SAM to the metal cages is performed after the radiation exposure and before any significant heating of the resist layer. As such, hydroxyl groups of the exposed region are not able to react (e.g., in a decomposition reaction) before the SAM is attached.

In an embodiment, the process 660 may continue with operation 663, which comprises forming a protective layer over the unexposed region with a selective deposition process. For example, an ASD process may be used in some embodiments. The protection layer may comprise a low-k dielectric material. For example, the protection layer may comprise SiOC, HfOₓ, or SnOₓ.

In an embodiment, the process 660 may continue with operation 664, which comprises developing the resist layer to remove the exposed region. In an embodiment, the exposed region may be dissolved by exposing the resist layer to a non-polar solvent. The modified unexposed region remains substantially unaltered by the developing process in order to provide a developed positive tone resist.

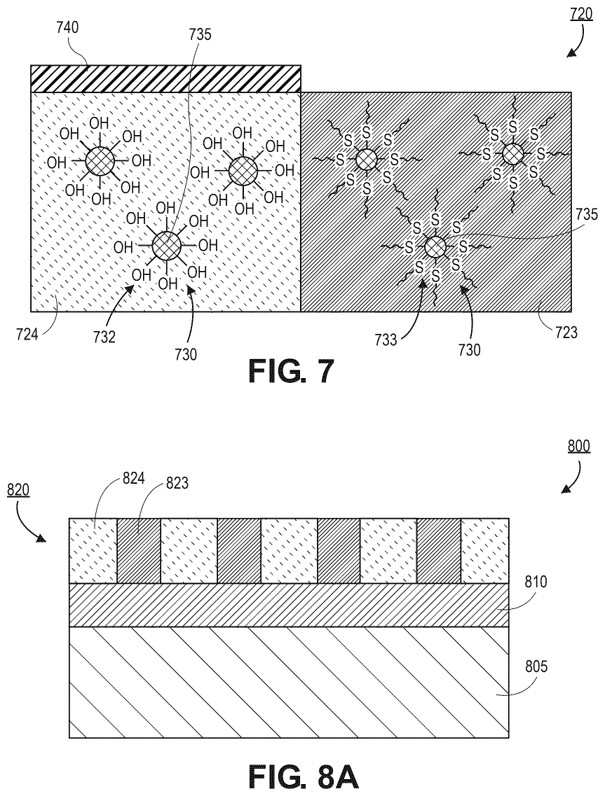

Referring now to FIG. 7, a cross-sectional illustration of a resist layer 720 is shown, in accordance with an additional embodiment. In an embodiment, the resist layer 720 may be similar to the resist layer 420 in FIG. 4 described above, with the exception of the unexposed region. For example, the resist layer 720 may comprise an exposed region 723 with metal cages 730 that comprise metal-oxide clusters 735 with a SAM 733 surrounding the metal-oxide clusters 735. The unexposed region may also comprise metal cages 730 with metal-oxide clusters 735. However, instead of alkyl terminations, the metal cages 730 may comprise hydroxyl terminations 732. The hydroxyl terminations 732 may be formed by exposing the resist layer to a blank UV radiation (or any other suitable type of radiation) before the protection layer 740 is formed.

In an embodiment, the presence of the hydroxyl terminations 732 may enhance the chemical contrast between the unexposed region 724 and the exposed region 723 compared to the chemical contrast described with respect to FIG. 4. Accordingly, an ASD process used to selectively deposit the protection layer 740 (e.g., a low-k dielectric material, such as SiOC, HfOₓ, SnOₓ, etc.) is easier to implement.

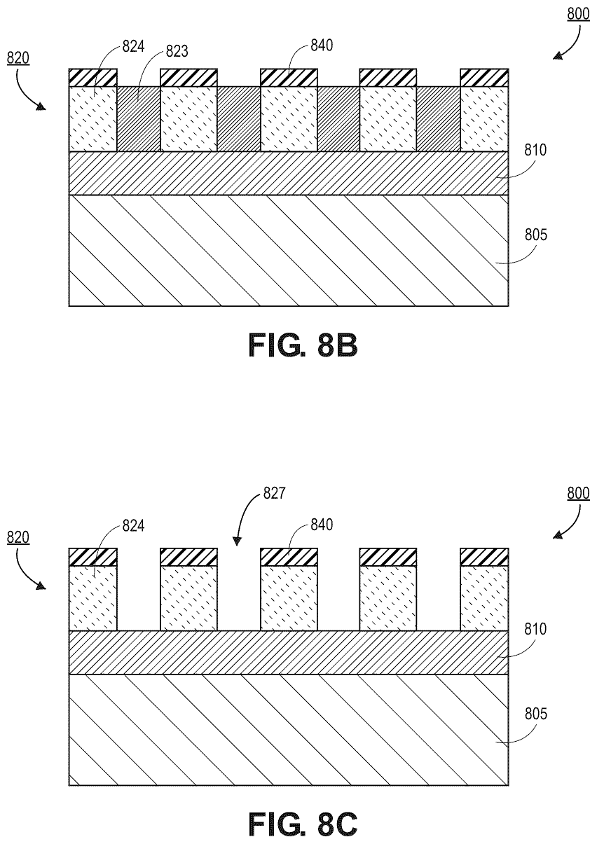

Referring now to FIGS. 8A-8C a series of cross-sectional illustrations depicting a process for selectively forming a protection layer over unexposed regions of a MOR is shown, in accordance with an embodiment.

Referring now to FIG. 8A, a cross-sectional illustration of the device 800 with a resist layer 820 over an underlayer 810 and a substrate 805 is shown, in accordance with an embodiment. In an embodiment, the device 800 in FIG. 8A may be similar to the device 200 in FIG. 2C. That is, the resist layer 820 may comprise a MOR material that has been exposed to include exposed regions 823 and unexposed regions 824. The exposed regions 823 may be treated so that a SAM is provided around the metal cages of the MOR material. After the SAM formation, a blanket exposure (e.g., to UV radiation) allows for the unexposed regions 824 to have metal cages with hydroxyl terminations. The process to form the device 800 in FIG. 8A may be similar to the processing used to form the device 200 in FIG. 2C.

Referring now to FIG. 8B, a cross-sectional illustration of the device 800 after a protection layer 840 is selectively formed over the unexposed regions 824 of the resist layer 820 is shown, in accordance with an embodiment. In an embodiment, the hydroxyl terminations of the unexposed regions 824 of the resist layer 820 may have a chemical contrast to the SAMs in the exposed regions 823. As such, an ASD process, such as one similar to the any of the ASD processes described herein, may be used in order to selectively form the protection layer 840 over the unexposed regions 824. That is, the exposed regions 823 remain exposed in FIG. 8B. In an embodiment, the protection layer 840 may be a low-k dielectric material. For example, the protection layer 840 may comprise SiOC, HfOₓ, or SnOₓ.

Referring now to FIG. 8C, a cross-sectional illustration of the device 800 after the resist layer 820 is developed is shown, in accordance with an embodiment. In an embodiment, the resist layer 820 may be developed with a non-polar solvent or the like. The non-polar solvent may selectively dissolve the SAM coated metal cages of the exposed regions 823 in order to form openings 827 through the resist layer 820. For example, the openings 827 may be holes that are used in the formation of vias in the underlying substrate 805. After the openings 827 are formed with the developing process, a pattern of the openings 827 may be transferred into the underlayer 810 and the substrate 805 using processes similar to any of those described with respect to FIG. 2F above.

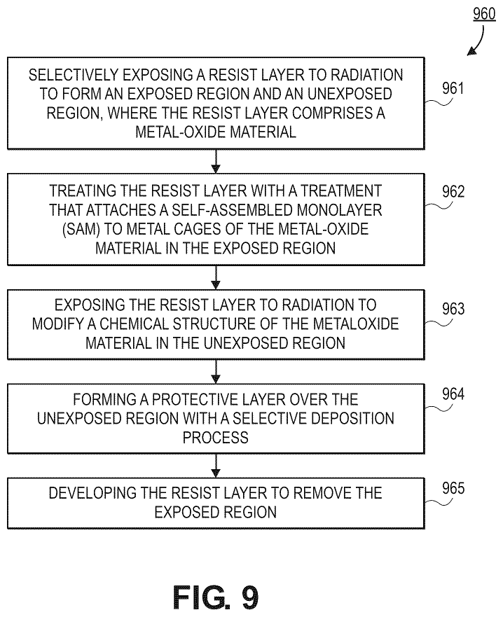

Referring now to FIG. 9, a flow diagram of a process 960 for developing a resist layer is shown, in accordance with an embodiment. In an embodiment, the resist layer may be a MOR material that is converted from a negative tone resist to a positive tone resist after radiation exposure. For example, the process 960 may be similar to the process described above with respect to FIGS. 8A-8C .

In an embodiment, the process 960 may begin with operation 961, which comprises selectively exposing a resist layer to radiation to form an exposed region and an unexposed region. In an embodiment, the radiation may include EUV radiation or DUV radiation. The resist layer may include a metal-oxide material, such as any of the MOR materials described in greater detail herein.

In an embodiment, the process 960 may continue with operation 962, which comprises treating the resist layer with a treatment that attaches a SAM to metal cages of the metal-oxide material in the exposed region. For example, the metal cages in the exposed region may have hydroxyl groups that react with sulfur of the SAM. In an embodiment, the treatment to attach the SAM to the metal cages is performed after the radiation exposure and before any significant heating of the resist layer. As such, hydroxyl groups of the exposed region are not able to react (e.g., in a decomposition reaction) before the SAM is attached.

In an embodiment, the process 960 may continue with operation 963, which comprises exposing the resist layer with radiation to modify a chemical structure of the metal-oxide material in the unexposed region. The radiation exposure may include UV radiation, DUV radiation, or EUV radiation. The exposure may be a blanket exposure (i.e., without a mask). The metal cages in the exposed region are protected from further chemical change by the SAM, and the metal cages in the unexposed region may be altered to have hydroxyl terminations.

In an embodiment, the process 960 may continue with operation 964, which comprises forming a protective layer over the unexposed region with a selective deposition process. For example, an ASD process may be used in some embodiments. The protection layer may comprise a low-k dielectric material. For example, the protection layer may comprise SiOC, HfOₓ, or SnOₓ.

In an embodiment, the process 960 may continue with operation 965, which comprises developing the resist layer to remove the exposed region. In an embodiment, the exposed region may be dissolved by exposing the resist layer to a non-polar solvent. The modified unexposed region remains substantially unaltered by the developing process in order to provide a developed positive tone resist.

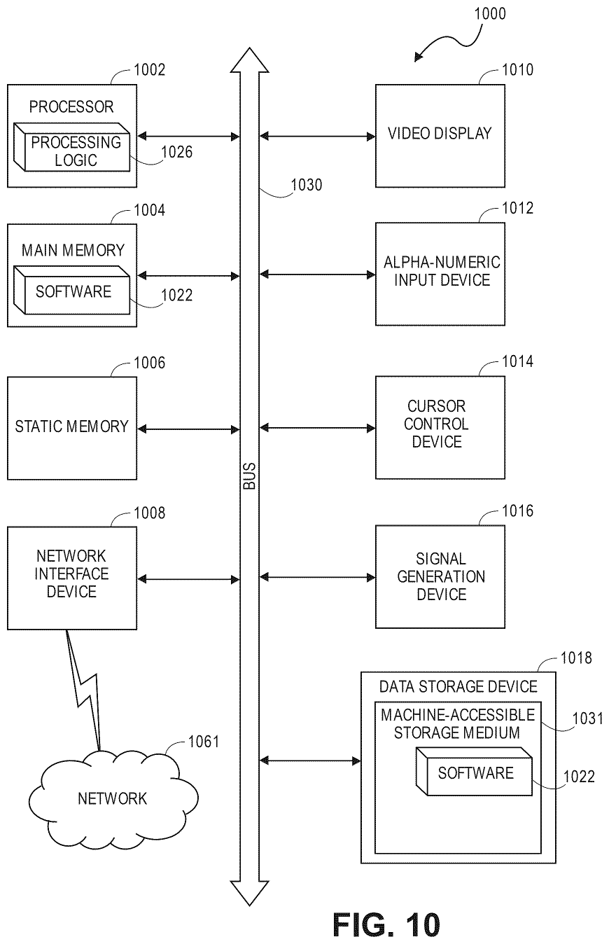

Referring now to FIG. 10, a block diagram of an exemplary computer system 1000 of a processing tool is illustrated in accordance with an embodiment. In an embodiment, computer system 1000 is coupled to and controls processing in the processing tool. Computer system 1000 may be connected (e.g., networked) to other machines in a Local Area Network (LAN), an intranet, an extranet, or the Internet. Computer system 1000 may operate in the capacity of a server or a client machine in a client-server network environment, or as a peer machine in a peer-to-peer (or distributed) network environment. Computer system 1000 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 1000, the term “machine” shall also be taken to include any collection of machines (e.g., computers) that individually or jointly execute a set (or multiple sets) of instructions to perform any one or more of the methodologies described herein.

Computer system 1000 may include a computer program product, or software 1022, having a non-transitory machine-readable medium having stored thereon instructions, which may be used to program computer system 1000 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 1000 includes a system processor 1002, a main memory 1004 (e.g., read-only memory (ROM), flash memory, dynamic random access memory (DRAM) such as synchronous DRAM (SDRAM) or Rambus DRAM (RDRAM), etc.), a static memory 1006 (e.g., flash memory, static random access memory (SRAM), etc.), and a secondary memory 1018 (e.g., a data storage device), which communicate with each other via a bus 1030.

System processor 1002 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 1002 may also be one or more special-purpose processing devices such as an application specific integrated circuit (ASIC), a field programmable gate array (FPGA), a digital signal system processor (DSP), network system processor, or the like. System processor 1002 is configured to execute the processing logic 1026 for performing the operations described herein.

The computer system 1000 may further include a system network interface device 1008 for communicating with other devices or machines. The computer system 1000 may also include a video display unit 1010 (e.g., a liquid crystal display (LCD), a light emitting diode display (LED), or a cathode ray tube (CRT)), an alphanumeric input device 1012 (e.g., a keyboard), a cursor control device 1014 (e.g., a mouse), and a signal generation device 1016 (e.g., a speaker).

The secondary memory 1018 may include a machine-accessible storage medium 1031 (or more specifically a computer-readable storage medium) on which is stored one or more sets of instructions (e.g., software 1022) embodying any one or more of the methodologies or functions described herein. The software 1022 may also reside, completely or at least partially, within the main memory 1004 and/or within the system processor 1002 during execution thereof by the computer system 1000, the main memory 1004 and the system processor 1002 also constituting machine-readable storage media. The software 1022 may further be transmitted or received over a network 1061 via the system network interface device 1008. In an embodiment, the network interface device 1008 may operate using RF coupling, optical coupling, acoustic coupling, or inductive coupling.

While the machine-accessible storage medium 1031 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method of treating a resist layer that comprises a metal-oxide material that has been selectively exposed with radiation to form an exposed region and an unexposed region, the method comprising:
treating the resist layer with a treatment that attaches a self-assembled monolayer (SAM) to metal cages of the metal-oxide material in the exposed region;
exposing the resist layer to radiation to modify a chemical structure of the metal-oxide material in the unexposed region; and
heating the resist layer to drive a condensation reaction in the unexposed region.

2. The method of claim 1, wherein the treatment comprises exposing the resist layer to a liquid.

3. The method of claim 1, wherein the treatment comprises exposing the resist layer to a gas.

4. The method of claim 1, wherein the treatment comprises exposing the resist layer to an alkanethiol or an alkylsilane.

5. The method of claim 1, wherein the resist layer is not heated between exposing the resist layer and treating the resist layer.

6. The method of claim 1, wherein the SAM comprises an alkyl chain, and wherein the alkyl chain is coupled to the metal cages by sulfur.

7. The method of claim 1, further comprising:
developing the resist layer to remove the exposed region.

8. The method of claim 7, wherein developing the resist layer comprises using a non-polar solvent to selectively remove the exposed region.

9. The method of claim 1, wherein the metal-oxide material comprises one or more of tin, indium, hafnium, zinc, zirconium.

10. A non-transitory computer readable medium comprising instructions that, when executed by at least one processor, cause a processing tool to perform the method of claim 1.

11. A method of treating a resist layer that comprises a metal-oxide material that has been selectively exposed with radiation to form an exposed region and an unexposed region, the method comprising:
treating the resist layer with a treatment that attaches a self-assembled monolayer (SAM) to metal cages of the metal-oxide material in the exposed region; and
forming a protective layer over the unexposed region with a selective deposition process.

12. The method of claim 11, wherein the protective layer is formed with an area selective deposition process that selectively deposits the protective layer over unexposed regions as a result of a chemical contrast between first alkyl groups of metal cages in the unexposed region and second alkyl groups of the SAM.

13. The method of claim 12, wherein the first alkyl groups have up to five carbons and the second alkyl groups have four or more carbons.

14. The method of claim 11, further comprising:
developing the resist layer with a non-polar solvent to remove the exposed region.

15. The method of claim 11, wherein the protective layer comprises SiOC, HfOₓ, or SnOₓ.

16. A method of treating a resist layer that comprises a metal-oxide material that has been selectively exposed with radiation to form an exposed region and an unexposed region, the method comprising:
treating the resist layer with a treatment that attaches a self-assembled monolayer (SAM) to metal cages of the metal-oxide material in the exposed region;
exposing the resist layer to radiation to modify a chemical structure of the metal-oxide material in the unexposed region; and
forming a protective layer over the unexposed region with a selective deposition process.

17. The method of claim 16, wherein the chemical structure of the metal-oxide material is modified to have OH group terminations on the metal cages of the metal-oxide material.

18. The method of claim 17, wherein the protective layer is formed with an area selective deposition process that selectively deposits the protective layer over unexposed regions as a result of a chemical contrast between the OH group terminations on the metal cages in the unexposed region and alkyl groups of the SAM.

19. The method of claim 16, wherein the radiation to modify the chemical structure of the metal-oxide material in the unexposed region is ultraviolet radiation.

20. The method of claim 16, wherein the protective layer comprises SiOC, HfOₓ, or SnOₓ.
